(19) United States
(12) Patent Application Publication
(10) Pub. No.: US 2016/0181538 A1
(43) Pub. Date: Jun. 23, 2016

(54) ELECTRO-OPTICAL DEVICE AND USE THEREOF

(71) Applicant: MERCK PATENT GMBH, Darmstadt (DE)

(72) Inventors: Aurelie Ludemann, Frankfurt Am Main (DE); Susanne Heun, Bad Soden (DE); Niels Schulte, Kelkheim (DE)

(73) Assignee: Merck Patent GmbH, Darmstadt (DE)

(21) Appl. No.: 14/908,384

(22) PCT Filed: Jul. 9, 2014
(86) PCT No.: PCT/EP2014/001880

§ 371 Date: Jan. 28, 2016

(30) Foreign Application Priority Data
Jul. 29, 2013 (DE) 13003771.6

(51) Int. Cl. H01L 51/00

(52) U.S. Cl. CPC H01L 51/0043; H01L 51/0037; H01L 51/0035; H01L 51/5004

(57) ABSTRACT

The present invention relates to an electro-optical device comprising a) an anode, b) a cathode, c) at least one emitter layer, which is arranged between the anode and the cathode, containing at least one semi-conductive, organic material, and d) at least one intermediate layer, which is arranged between the at least one emitter layer and the anode, and which contains a polymer having hole-conducting structural units. The device is characterized in that the polymer having hole-conducting structural units additionally have structural units having electron-conducting properties. The devices according to the invention have significantly longer service lives compared to known devices.

The present invention relates to a novel design principle for organic electrooptical devices, especially for electroluminescent elements, and to the use thereof in displays and lighting means based thereon.

In a number of different kinds of applications which can be attributed to the electronics industry in the broadest sense, the use of organic semiconductors as functional materials has been reality for some time or is expected in the near future.

For instance, light-sensitive organic materials (e.g. phthalocyanines) and organic charge transport materials (e.g. triarylamine-based hole transporter materials) have already been used for several years in photocopiers.

Some specific semiconductive organic compounds, some of which are also capable of emitting light in the visible spectral region, are now already being used in commercially available devices, for example in organic electroluminescent devices.

The individual components thereof, organic light-emitting diodes (OLEDs), have a very broad spectrum of application. OLEDs are already finding use, for example, as:
white or colored backlighting for monochrome or multicolor display elements (for example in pocket calculators, mobile phones and other portable applications),
large-area displays (for example as traffic signs or posters),
lighting elements in a wide variety of different colors and forms,
monochrome or full-color passive matrix displays for portable applications (for example for mobile phones, PDAs and camcorders),
full-color large-area and high-resolution active matrix displays for a wide variety of different applications (for example for mobile phones, PDAs, laptops and televisions).

Development in some of these applications is already very advanced. There is nevertheless still a great need for technical improvements.

There is currently intensive study of conjugated polymers as promising materials for polymeric OLEDs, called PLEDs. The ease of processing thereof, in contrast to vapor-deposited arrangements made from small molecules, called small molecule devices (“SMOLEDs”), promises less expensive production of organic light-emitting diodes. The use of interlayers in a layer structure, as described, for example, in WO 04/084260, has distinctly increased the lifetime and efficiency of PLEDs. These interlayers are applied between anode and the layer of light-emitting polymers. Their function is to facilitate, or to actually make possible, the injection and transport of holes, i.e. of positive charge carriers, into the light-emitting polymer, and to block electrons at the interface between interlayer and layer of light-emitting polymer. These interlayers consist of polymers having a high proportion of hole-transporting units joined via a conjugated backbone. In addition, these polymers simultaneously block the transport of electrons.

Although electrooptical devices which have been constructed using such interlayers show distinct advantages in relation to lifetime and efficiency over arrangements lacking such interlayers, both characteristics are still a long way short of meeting the demands that would be needed for use in large-area displays. The known systems of this type thus have particular shortcomings with regard to lifetime. Moreover, these systems exhibit an intolerable rise in voltage during operation.

It has now been found that, surprisingly, electrooptical devices exhibit much longer lifetimes when polymers which are copolymerized with electron conductors are used as interlayers. This goes beyond the prior art to a crucial degree, since there is no longer any electron-blocking action here, which was regarded as an essential function of interlayers.

Proceeding from this prior art, it was an object of the present invention to provide an electrooptical device which is producible by simple application methods from solution, and which has a longer lifetime compared to known devices.

The present invention thus provides an electrooptical device comprising
a) an anode,
b) a cathode,
c) at least one emitter layer disposed between anode and cathode, comprising at least one semiconductive organic material, and
d) at least one interlayer which is disposed between the at least one emitter layer and the anode and comprises a polymer having hole-conducting structural units,
   which is characterized in that the polymer having hole-conducting structural units additionally has structural units having electron-conducting properties.

The device of the invention is characterized by the use of one or more interlayers composed of selected polymeric materials.

The copolymers which form the interlayer must have hole-conducting properties and simultaneously electron-conducting properties. This profile of properties can be created through selection of suitable structural units which form the copolymer.

The structural units having electron-conducting properties are selected such that they have a LUMO (“Lowest Unoccupied Molecular Orbital”) lower than the LUMO of the semiconductive organic material in the emitter layer. This is the case in the conventionally used emitter materials when the LUMO of the structural units having electron-conducting properties is less than −2.3 eV. Preferably, the LUMO of the electron-conducting structural unit in the interlayer is less than −2.4 eV, preferably less than −2.5 eV and especially less than −2.6 eV.

Preferably, the LUMO of the electron-conducting structural unit in the interlayer is more than 0.1 eV, more preferably more than 0.15 eV and especially more than 0.2 eV lower than the LUMO of the at least one semiconductive organic material in the emitter layer.

Of the various energy levels that chemical compounds have, the HOMO (“Highest Occupied Molecular Orbital”) and the LUMO (“Lowest Unoccupied Molecular Orbital”) in particular play a major role.

These energy levels can be determined by photoemission, e.g. XPS (X-ray Photoelectron Spectroscopy) and UPS (Ultraviolet Photoelectron Spectroscopy), or by cyclic voltammetry (“CV”) for the oxidation and reduction.

For some time, it has also been possible to determine the energy levels of the molecular orbitals, especially of the occupied molecular orbitals, via quantum-chemical calculation methods, for example by means of Density Functional Theory (“DFT”). A detailed description of such quantum-chemical calculations can be found in WO 2012/171609.

In principle, any electron transport material (ETM) known to those skilled in the art may be used as repeat unit in the polymers in the interlayer according to the present invention. Suitable ETMs are selected from the group consisting of imidazoles, pyridines, pyrimidines, pyridazines, pyrazines, oxadiazoles, quinolines, quinoxalines, anthracenes, benzanthracenes, pyrenes, perylenes, benzimidazoles, triazines, ketones, phosphine oxides, phenazines, phenanthrolines, triarylboranes and the isomers and derivatives thereof.

Further suitable ETM structural units are metal chelates of 8-hydroxyquinoline (e.g. Liq, Alq₃, Gaq₃, Mgq₂, Znq₂, Inq₃, Zrq₄), Balq, 4-azaphenanthren-5-ol/Be complexes (U.S. Pat. No. 5,529,853 A; e.g. formula 7), butadiene derivatives (U.S. Pat. No. 4,356,429), heterocyclic optical brighteners (U.S. Pat. No. 4,539,507), benzazoles, for example 1,3,5-tris(2-N-phenylbenzimidazolyl)benzene (TPBI) (U.S. Pat. No. 5,766,779, formula 8), 1,3,5-triazine derivatives (U.S. Pat. No. 6,229,012 B1, U.S. Pat. No. 6,225,467 B1, DE 10312675 A1, WO 98/04007 A1 and U.S. Pat. No. 6,352,791 B1), pyrenes, anthracenes, tetracenes, fluorenes, spirobifluorenes, dendrimers, tetracenes, e.g. rubrene derivatives, 1,10-phenanthroline derivatives (JP 2003/115387, JP 2004/311184, JP 2001/267080 and WO 2002/043449), silacylcyclopentadiene derivatives (EP 1480280, EP 1478032 and EP 1469533), pyridine derivatives (JP 2004/200162 Kodak), phenanthrolines, e.g. BCP and Bphen, and a number of phenanthrolines bonded via biphenyl or other aromatic groups (US 2007/0252517 A1) or anthracene-bonded phenanthrolines (US 2007/0122656 A1, e.g. formulae 9 and 10), 1,3,4-oxadiazoles, e.g. formula 11, triazoles, e.g. formula 12, triarylboranes, benzimidazole derivatives and other N-heterocyclic compounds (US 2007/0273272 A1), borane derivatives, Ga-oxinoid complexes.

A preferred ETM structural unit is selected from a unit of the formula (1) having a C=X group in which X=O, S or Se, preferably O, as disclosed, for example, in WO 2004/093207 A2 and WO 2004/013080 A1.

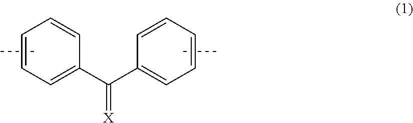

More preferably, the structural units of the formula (1) are fluorene ketones, spirobifluorene ketones or indenofluorene ketones of the formulae (1a), (1b) and (1c)

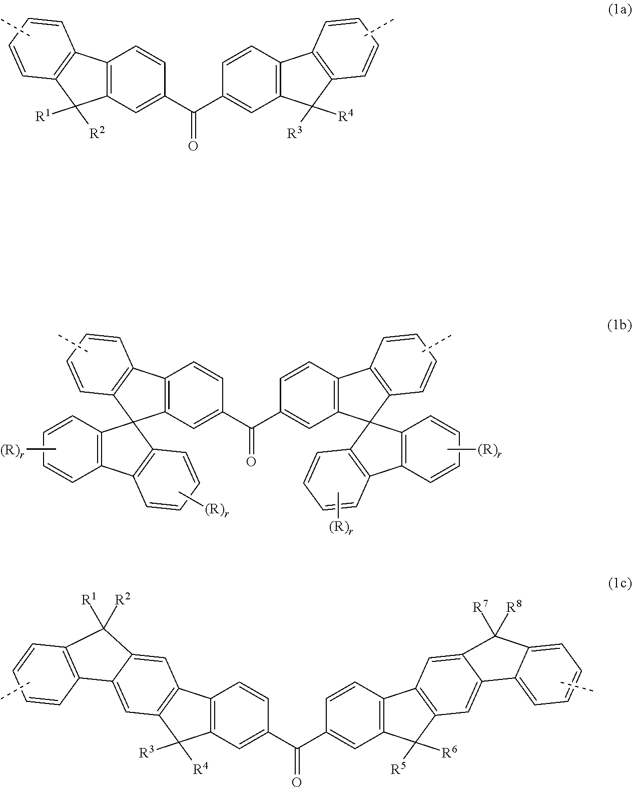

in which R and R¹ to R⁸ are each independently a hydrogen atom, a substituted or unsubstituted aromatic cyclic hydrocarbyl group having 6 to 50 carbon atoms in the ring, a substituted or unsubstituted aromatic heterocyclic group having 5 to 50 ring atoms, a substituted or unsubstituted alkyl group having 1 to 50 carbon atoms, a substituted or unsubstituted cycloalkyl group having 3 to 50 carbon atoms in the ring, a substituted or unsubstituted alkoxy group having 1 to 50 carbon atoms, a substituted or unsubstituted aralkyl group having 6 to 50 carbon atoms in the ring, a substituted or unsubstituted aryloxy group having 5 to 50 carbon atoms in the ring, a substituted or unsubstituted arylthio group having 5 to 50 carbon atoms in the ring, a substituted or unsubstituted alkoxycarbonyl group having 1 to 50 carbon atoms, a substituted or unsubstituted silyl group having 1 to 50 carbon atoms, a carboxyl group, a halogen atom, a cyano group, a nitro group or a hydroxyl group. One or more of the R¹ and R², R³ and R⁴, R⁵ and R⁶, and R⁷ and R⁸ pairs optionally form a ring system, and r is 0, 1, 2, 3 or 4.

Further preferred ETM structural units are selected from the group consisting of imidazole derivatives and benzimidazole derivatives of the formula (2), as disclosed, for example, in US 2007/0104977 A1,

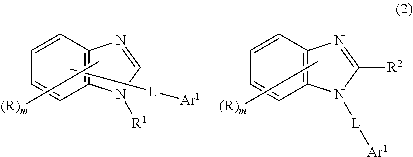

where
R is a hydrogen atom, a C6-C60-aryl group, a pyridyl group, a quinolyl group, a C1-20-alkyl group or a C1-20-alkoxy group; where these groups may be unsubstituted or substituted by one or more R² radicals;
m is an integer from 0 to 4;
R¹ is a C6-C60-aryl group, a pyridyl group, a quinolyl group, a C1-20-alkyl group or a C1-20-alkoxy group; where these groups may be unsubstituted or substituted by one or more R² radicals;
R² is a hydrogen atom, a C6-60-aryl group, a pyridyl group, a quinolyl group, a C1-20-alkyl group or a C1-20-alkoxy group;
L is a C6-60-arylene group, a pyridinylene group, a quinolinylene or a fluorenylene group, where these groups may be unsubstituted or substituted by one or more R² radicals, and
Ar¹ is a C6-60-aryl group, a pyridinyl group or a quinolinyl group, where these groups may be unsubstituted or substituted by one or more R² radicals.

Preference is further given to 2,9,10-substituted anthracenes (by 1- or 2-naphthyl and 4- or 3-biphenyl) or molecules containing two anthracene units as disclosed, for example, in US 2008/0193796 A1.

In a further preferred embodiment, the ETM materials are selected from heteroaromatic ring systems of the following formulae (3) to (8):

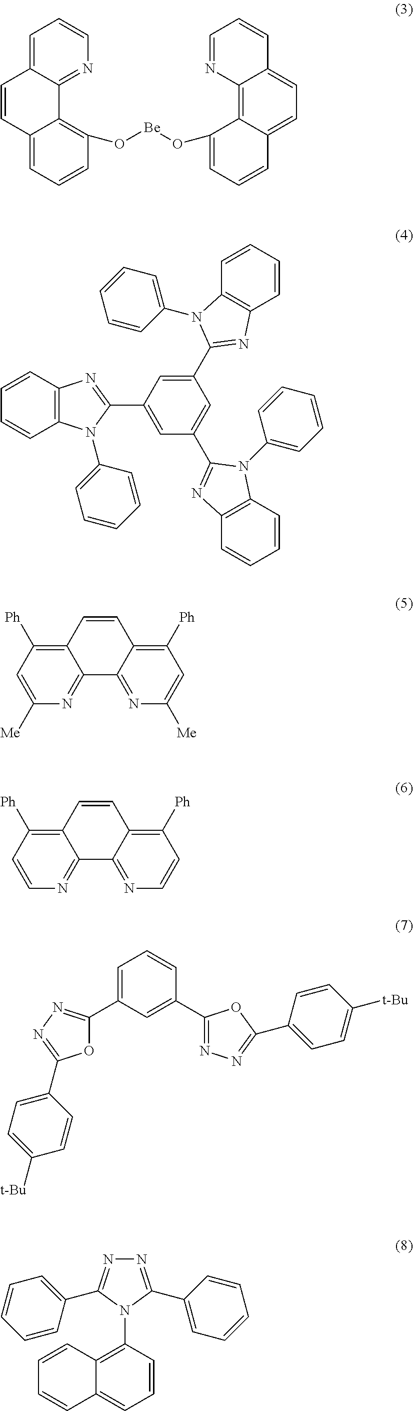

Particular preference is given to anthracenebenzimidazole derivatives of the formulae (9) to (11) as disclosed, for example, in U.S. Pat. No. 6,878,469 B2, US 2006/147747 A and EP 1551206 A1:

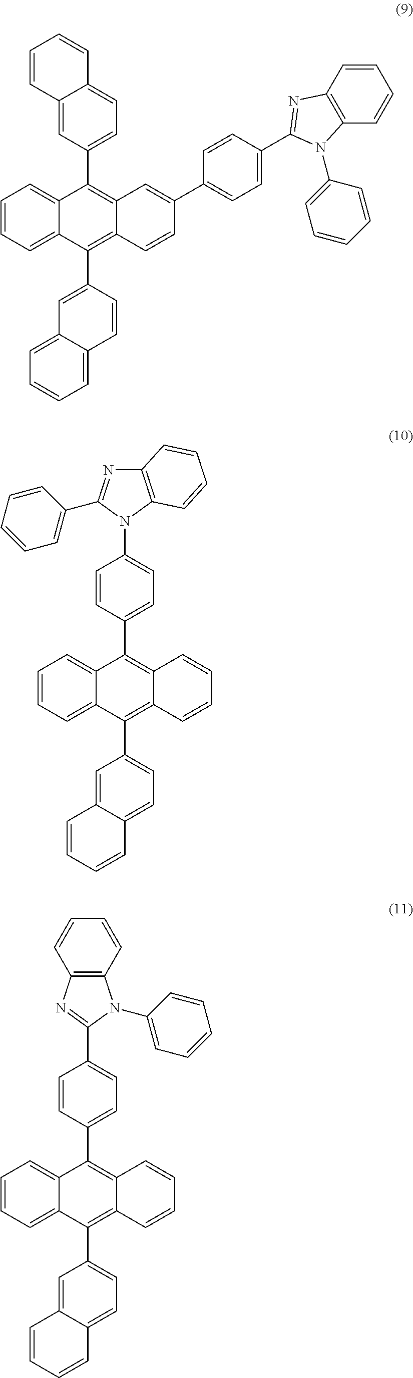 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

Examples of polymers containing an ETM structural unit and the corresponding syntheses are disclosed as in US 2003/0170490 A1 for triazine as ETM unit.

Copolymers used with preference for the interlayer contain structural units having electron-conducting properties which derive from benzophenone, triazine, imidazole, benzimidazole or perylene units which may optionally be substituted. Examples of these are benzophenone, aryltriazine, benzimidazole and diarylperylene units.

Particular preference is given to using copolymers containing structural units having electron-conducting properties selected from the structural units of the following formulae (I) to (IV):

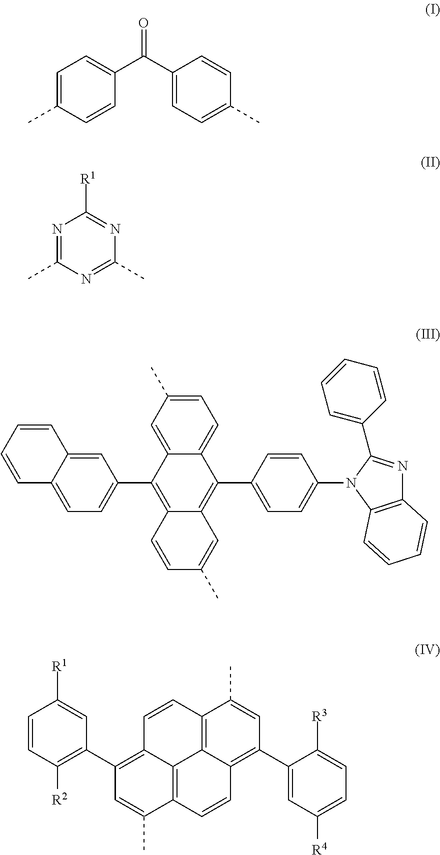

where R¹ to R⁴ can assume the same definitions as R¹ to R⁴ in the formula (1a).

The proportion of the structural units having electron-conducting properties in the hole-conducting polymer which is used in the interlayer is preferably in the range from 0.01 to 30 mol %, more preferably in the range from 1 to 15 mol % and especially in the range from 1 to 4 mol %.

The hole-conducting properties of the copolymer used in the interlayer are likewise achieved via the selection of suitable structural units. The hole transport interlayer contains at least one repeat unit selected from the group of the hole transport materials (HTM), optionally and preferably together with at least one repeat unit which forms the polymer backbone.

In principle, it is possible to use any HTM known to those skilled in the art as repeat unit in the polymer of the invention. Such an HTM is preferably selected from amines, triarylamines, thiophenes, carbazoles, phthalocyanines, porphyrins and isomers and derivatives thereof. The HTM is more preferably selected from amines, triarylamines, thiophenes, carbazoles, phthalocyanines and porphyrins.

Suitable HTM units are phenylenediamine derivatives (U.S. Pat. No. 3,615,404), arylamine derivatives (U.S. Pat. No. 3,567,450), amino-substituted chalcone derivatives (U.S. Pat. No. 3,526,501), styrylanthracene derivatives (JP A 56-46234), polycyclic aromatic compounds (EP 1009041), polyarylalkane derivatives (U.S. Pat. No. 3,615,402), fluorenone derivatives (JP A 54-110837), hydrazone derivatives (U.S. Pat. No. 3,717,462), stilbene derivatives (JP A 61-210363), silazane derivatives (U.S. Pat. No. 4,950,950), polysilanes (JP A 2-204996), aniline copolymers (JP A 2-282263), thiophene oligomers, polythiophenes, PVK, polypyrroles, polyanilines and further copolymers, porphyrin compounds (JP A 63-2956965), aromatic dimethylidene-like compounds, carbazole compounds, for example CDBP, CBP, mCP, aromatic tertiary amine and styrylamine compounds (U.S. Pat. No. 4,127,412) and monomeric triarylamines (U.S. Pat. No. 3,180,730).

Preference is given to aromatic tertiary amines containing at least two tertiary amine units (U.S. Pat. No. 4,720,432 and U.S. Pat. No. 5,061,569), for example 4,4′-bis[N-(1-naphthyl)-N-phenylamino]biphenyl (NPD) (U.S. Pat. No. 5,061,569) or MTDATA (JP A 4-308688), N,N,N′,N′-tetra(4-biphenyl)diaminobiphenylene (TBDB), 1,1-bis(4-di-p-tolylaminophenyl)cyclohexane (TAPC), 1,1-bis(4-di-p-tolylaminophenyl)-3-phenylpropane (TAPPP), 1,4-bis[2-[4-[N,N-di(p-tolyl)amino]phenyl]vinyl]benzene (BDTAPVB), N,N,N′,N′-tetra-p-tolyl-4,4′-diaminobiphenyl (TTB), TPD, N,N,N′,N′-tetraphenyl-4,4′″-diamino-1,1′:4′,1″:4″,1′″-quaterphenyl, and likewise tertiary amines containing carbazole units, for example 4-(9H-carbazol-9-yl)-N,N-bis[4-(9H-carbazol-9-yl)phenyl]benzenamine (TCTA). Preference is likewise given to hexaazatriphenylene compounds according to US 2007/0092755 A1.

Particular preference is given to the following triarylamine compounds of the formulae (12) to (17) which may also be substituted by one or more R radicals (of formula (1b)), as disclosed in EP 1162193 A1, EP 650955 A1, Synth. Metals 1997, 91(1-3), 209, DE 19646119 A1, WO 2006/122630 A1, EP 1860097 A1, EP 1834945 A1, JP 08053397 A, U.S. Pat. No. 6,251,531 B1 and WO 2009/041635.

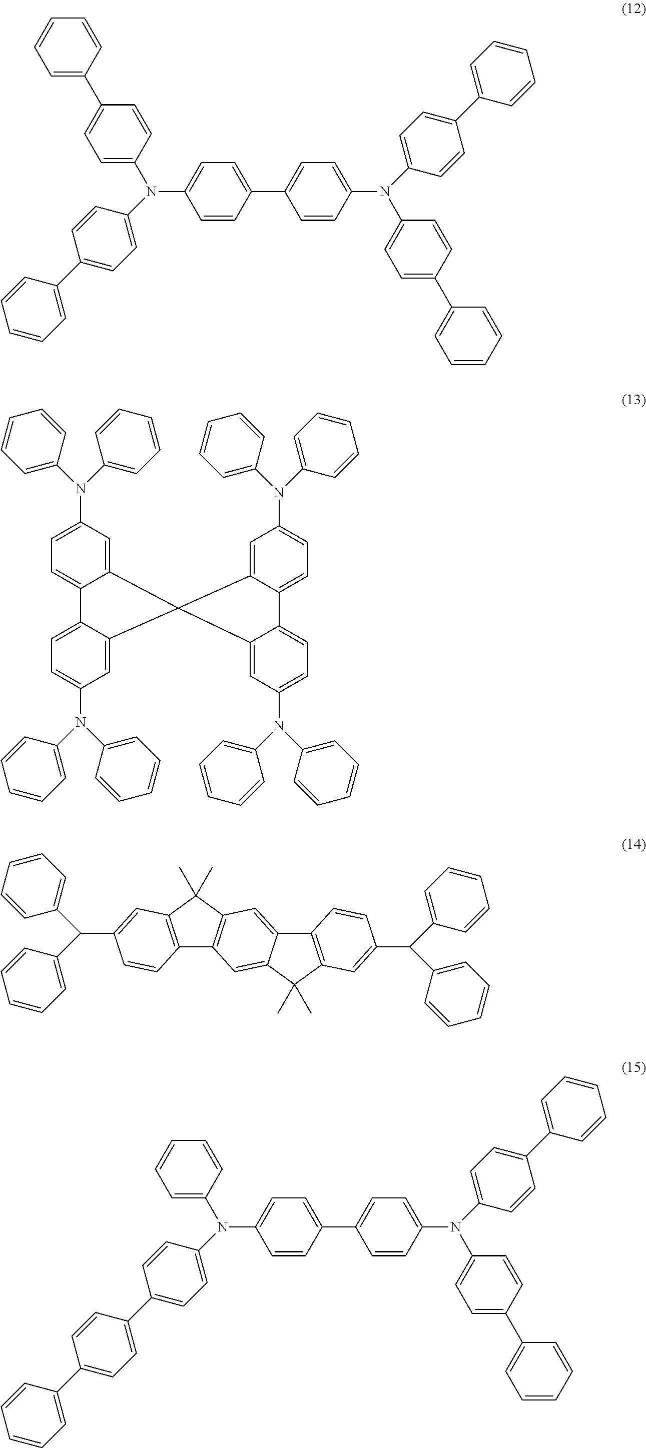

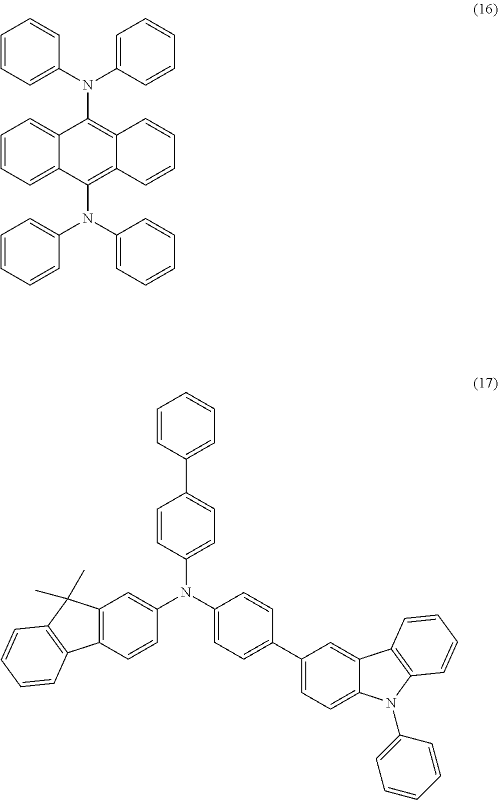 [SMILES: c1ccc(N(c2ccccc2)c2c3ccccc3c(N(c3ccccc3)c3ccccc3)c3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

Further preferred HTM units are, for example, triarylamine, benzidine, tetraaryl-para-phenylenediamine, carbazole, azulene, thiophene, pyrrole and furan derivatives, and additionally O-, S- or N-containing heterocycles.

Particular preference is given to HTM structural units of the following formula (18):

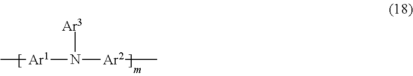

where
Ar¹, which may be the same or different, independently when in different repeat units, are a single bond or an optionally substituted monocyclic or polycyclic aryl group,
Ar², which may be the same or different, independently when in different repeat units, are an optionally substituted monocyclic or polycyclic aryl group,
Ar³, which may be the same or different, independently when in different repeat units, are an optionally substituted monocyclic or polycyclic aryl group, and
m is 1, 2 or 3.

Particularly preferred units of the formula (18) are units of the following formulae (19) to (21):

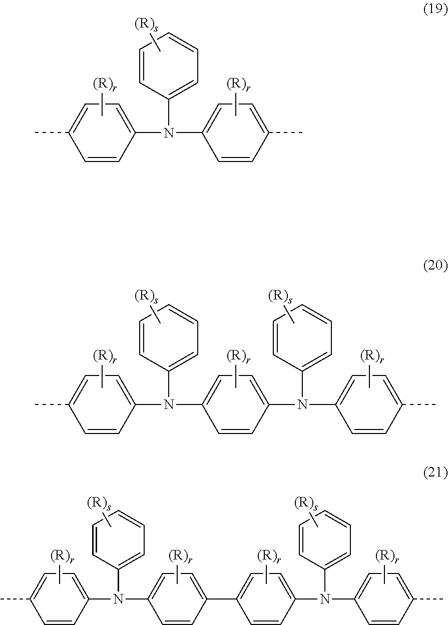

where
R, which may be the same or different at each instance, is selected from H, substituted or unsubstituted aromatic or heteroaromatic group, alkyl group, cycloalkyl group, alkoxy group, aralkyl group, aryloxy group, arylthio group, alkoxycarbonyl group, silyl group, carboxyl group, a halogen atom, cyano group, nitro group and hydroxyl group,
r is 0, 1, 2, 3 or 4 and
s is 0, 1, 2, 3, 4 or 5.

A further preferred interlayer polymer contains at least one repeat unit of the following formula (22):

-(T¹)_{c}-(Ar⁴)_{d}-(T²)ₑ-(Ar⁵)_{f} (22)

where
T¹ and T² are each independently selected from thiophene, selenophene, thieno[2,3b]thiophene, thieno[3,2b]thiophene, dithienothiophene, pyrrole, aniline, all optionally substituted by R⁹,
R⁹ independently at each instance is selected from halogen, —CN, —NC, —NCO, —NCS, —OCN, SCN, C(═O)NR⁰R⁰⁰, —C(═O)X, —C(═O)R⁰, —NH₂, —NR⁰R⁰⁰, SH, SR⁰, —SO₃H, —SO₂R⁰, —OH, —NO₂, —CF₃, —SF₅, optionally substituted silyl, or carbyl or hydrocarbyl which has 1 to 40 carbon atoms and is optionally substituted and optionally contains one or more heteroatoms,
Ar⁴ and Ar⁵ are independently monocyclic or polycyclic aryl or heteroaryl which is optionally substituted and optionally fused to the 2,3 positions of one or both of the adjacent thiophene or selenophene groups,
c and e are independently 0, 1, 2, 3 or 4, where 1<c+e≦6, and
d and f are independently 0, 1, 2, 3 or 4.

The T¹ and T² groups are preferably selected from

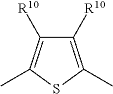

thiophene-2,5-diyl,

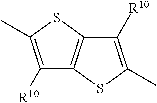

thieno[3,2-b]thiophene-2,5-diyl,

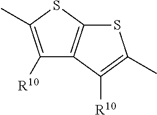

thieno[2,3-b]thiophene-2,5-diyl,

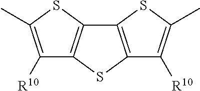

dithienothiophene-2,6-diyl and

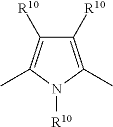

pyrrole-2,5-diyl,
where R¹⁰ can assume the same definitions as R¹ in the formula (1a).

Preferred units of the formula (22) are selected from the following formulae:

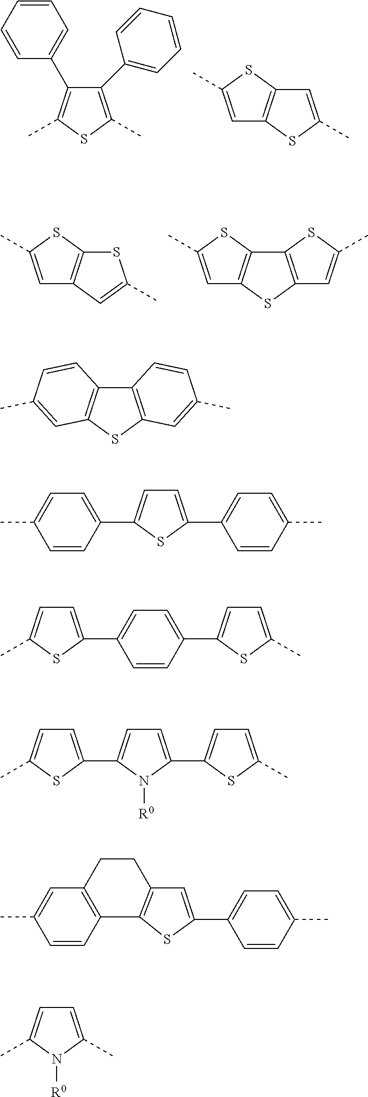

Examples of hole-transporting interlayer polymers are disclosed in WO 2007/131582 A1 and in WO 2008/009343 A1.

The proportion of the structural units having hole-conducting properties in the hole-conducting polymer which is used in the interlayer is preferably in the range from 10 to 99 mol %, more preferably in the range from 20 to 80 mol % and especially in the range from 40 to 60 mol %.

Preferably, the polymers of the invention contain, as repeat units which form the polymer backbone, aromatic or heteroaromatic structural units having 6 to 40 carbon atoms. These are preferably 4,5-dihydropyrene derivatives, 4,5,9,10-tetrahydropyrene derivatives, fluorene derivatives as disclosed, for example, in U.S. Pat. No. 5,962,631, in WO 2006/052457 A2 and in WO 2006/118345 A1, 9,9′-spirobifluorene derivatives as disclosed, for example, in WO 2003/020790 A1, 9,10-phenanthrene derivatives as disclosed, for example, in WO 2005/104264 A1, 9,10-dihydrophenanthrene derivatives as disclosed, for example, in WO 2005/014689 A2, 5,7-dihydrodibenzoxepine derivatives and cis- and trans-indenofluorene derivatives as disclosed, for example, in WO 2004/041901 A1 and in WO 2004/113412 A2, binaphthylene derivatives as disclosed, for example, in WO 2006/063852 A1, and additionally units, as disclosed, for example, in WO 2005/056633 A1, in EP 1344788 A1, in WO 2007/043495 A1, in WO 2005/033174 A1, in WO 2003/099901 A1 and in DE 102006003710 A.

Further preferred structural elements for repeat units which form the polymer backbone are selected from fluorene derivatives, as disclosed, for example, in U.S. Pat. No. 5,962,631, in WO 2006/052457 A2 and in WO 2006/118345 A1, spirobifluorene derivatives, as disclosed, for example, in WO 2003/020790 A1, benzofluorene, dibenzofluorene, benzothiophene and dibenzofluorene and derivatives thereof, as disclosed, for example, in WO 2005/056633 A1, in EP 1344788 A1 and in WO 2007/043495 A1.

Particularly preferred structural elements for repeat units which form the polymer backbone are units of the following formula (23):

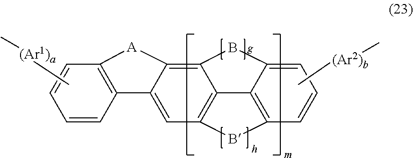

where
A, B and B′ are independently, and independently of one another in the case of multiple instances, a divalent group, preferably selected from —CR¹¹R¹²—, —NR¹¹—, —PR¹¹—, —O—, —S—, —SO—, —SO₂—, —CO—, —CS—, —CSe—, —P(═O)R¹¹—, —P(═S)R¹¹— and —SiR¹¹R¹²—,
R¹¹ and R¹² are independently identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, —SF₅, optionally substituted silyl, or carbyl or hydrocarbyl which has 1 to 40 carbon atoms and is optionally substituted and optionally contains one or more heteroatoms, and the R¹¹ and R¹² groups optionally form a spiro group together with the fluorene moiety to which they are bonded,
X is halogen,
R⁰ and R⁰⁰ are independently H or an optionally substituted carbyl or hydrocarbyl group optionally containing one or more heteroatoms,
each g is independently 0 or 1 and the respective corresponding h in the same subunit is the other of 0 and 1,
m is an integer ≧1,
Ar¹ and Ar² are independently mono- or polycyclic aryl or heteroaryl which is optionally substituted and optionally fused to the 7,8 positions or 8,9 positions of the indenofluorene group, and
a and b are independently 0 or 1.

If the R¹¹ and R¹² groups together with the fluorene group to which they are bonded form a spiro group, the structure is preferably spirobifluorene.

The units of the formula (23) are preferably selected from the following formulae (24) to (28):

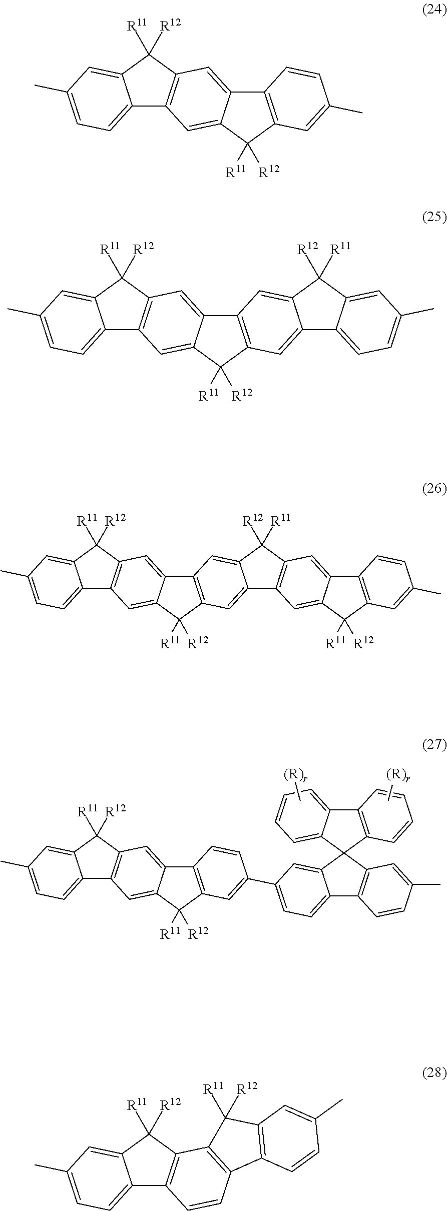

where R¹¹ and R¹² are as defined in formula (23), r is 0, 1, 2, 3 or 4 and R has one of the definitions of R¹¹.

Preferably, R is F, Cl, Br, I, —CN, —NO₂, —NCO, —NCS, —OCN, —SCN, —C(═O)NR⁰R⁰⁰, —C(═O)X, —C(═O)R⁰, —NR⁰R⁰⁰, optionally substituted silyl, aryl or heteroaryl having 4 to 40 and preferably 6 to 20 carbon atoms, or straight-chain, branched or cyclic alkyl, alkoxy, alkylcarbonyl, alkoxycarbonyl, alkylcarbonyloxy or alkoxycarbonyloxy having 1 to 20 and preferably 1 to 12 carbon atoms, in which one or more hydrogen atoms are optionally replaced by F or Cl and in which R⁰, R⁰⁰ and X are as defined above in relation to formula (23).

Particularly preferred units of the formula (23) are units of the following formulae (29) to (32):

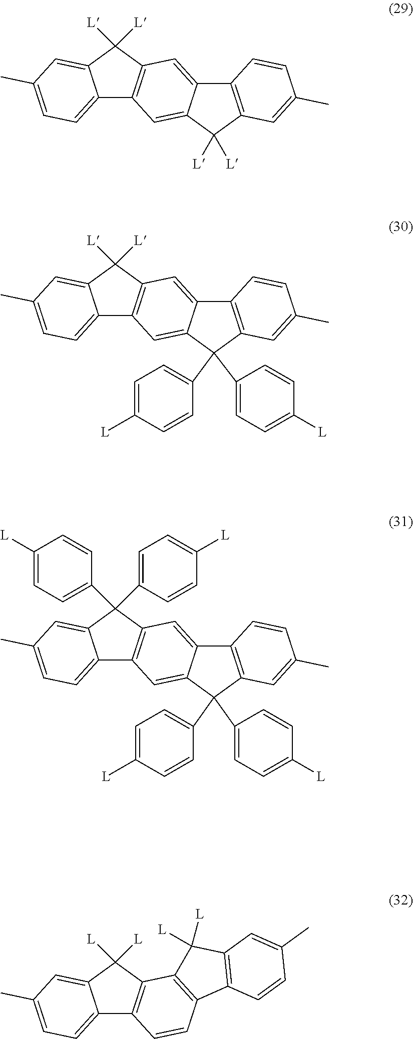

where
L is H, halogen or optionally fluorinated linear or branched alkyl or alkoxy having 1 to 12 carbon atoms and preferably H, F, methyl, i-propyl, t-butyl, n-pentoxy or trifluoromethyl and
L′ is optionally fluorinated linear or branched alkyl or alkoxy having 1 to 12 carbon atoms and preferably n-octyl or n-octyloxy.

In a further preferred embodiment, the interlayer polymer according to the present invention is a non-conjugated or partly conjugated polymer.

A particularly preferred non-conjugated or partly conjugated interlayer polymer contains a non-conjugated backbone repeat unit.

A preferred non-conjugated backbone repeat unit is a unit of an indenofluorene derivative of the formulae (33) and (34), as disclosed, for example, in WO 2010/136110,

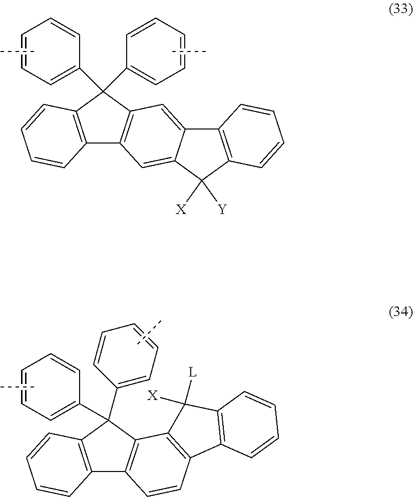

X and Y are independently selected from the group consisting of H, F, a C₁₋₄₀-alkyl group, a C₂₋₄₀-alkenyl group, a C₂₋₄₀-alkynyl group, an optionally substituted C₆₋₄₀-aryl group and an optionally substituted 5- to 25-membered heteroaryl group.

Further preferred non-conjugated backbone repeat units are units containing fluorene, phenanthrene, dihydrophenanthrene or indenofluorene derivatives of the following formulae, as disclosed, for example, in WO 2010/136111:

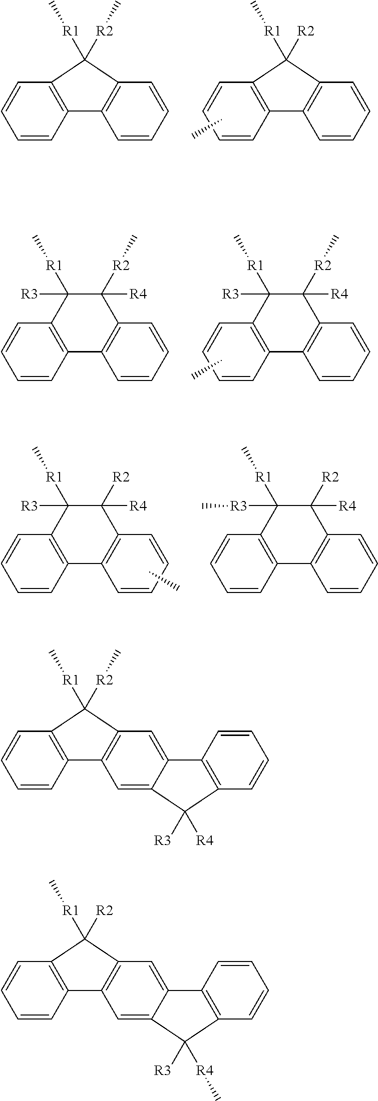

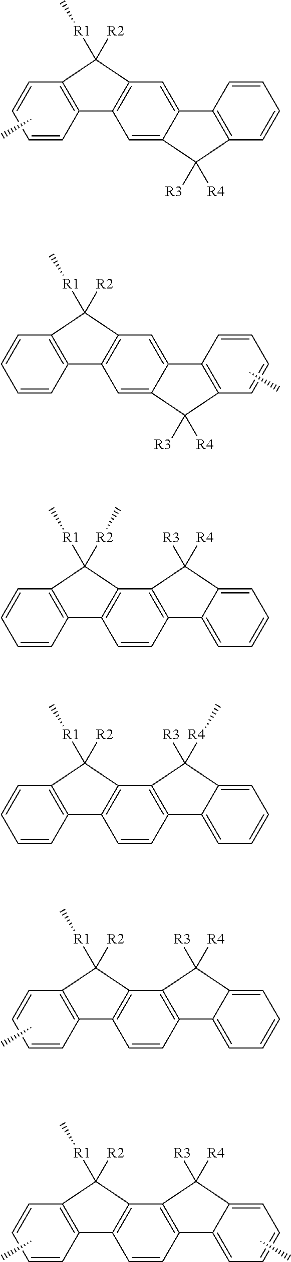

where R1-R4 may assume the same definitions as X and Y in the formulae (33) and (34).

The proportion of the structural units that form the polymer backbone in the hole-conducting polymer of the invention which is used in the interlayer is preferably in the range from 10 to 99 mol %, more preferably in the range from 20 to 80 mol % and especially in the range from 30 to 60 mol %.

The semiconductive organic material for the emitter layer(s) may be a polymeric matrix material which contains one or more different emitters incorporated within the polymer skeleton, or may be a polymeric and non-emitting matrix material into which one or more low molecular weight emitters have been mixed, or may be mixtures of different polymers having emitters incorporated within the polymer skeleton, or may be mixtures of different non-emitting matrix polymers with different low molecular weight emitters, or may be mixtures of at least one low molecular weight matrix material with different low molecular weight emitters, or may be any desired combinations of these materials.

The emitter layer contains at least one emitter, optionally and preferably at least one further matrix material.

In principle, it is possible to use any emitter known to those skilled in the art as emitter in the emitter layer of the device of the invention.

In a preferred embodiment, the emitter is integrated into a polymer as a repeat unit.

In a further preferred embodiment, the emitter is mixed into a matrix material which may be a small molecule, a polymer, an oligomer, a dendrimer or a mixture thereof.

Preference is given to an emitter layer comprising at least one emitter selected from fluorescent compounds, phosphorescent compounds and emitting organometallic complexes.

The expression “emitter unit” or “emitter” refers here to a unit or compound where radiative decay with emission of light occurs on acceptance of an exciton or formation of an exciton.

There are two emitter classes: fluorescent and phosphorescent emitters. The expression “fluorescent emitter” relates to materials or compounds which undergo a radiative transition from an excited singlet state to its ground state. The expression “phosphorescent emitter” as used in the present application relates to luminescent materials or compounds containing transition metals. These typically include materials where the emission of light is caused by spin-forbidden transition(s), for example transitions from excited triplet and/or quintuplet states.

According to quantum mechanics, the transition from excited states having high spin multiplicity, for example from excited triplet states, to the ground state is forbidden. However, the presence of a heavy atom, for example iridium, osmium, platinum and europium, ensures strong spin-orbit coupling, meaning that the excited singlet and triplet become mixed, and so the triplet gains a certain singlet character, and luminance can be efficient when the singlet-triplet mixture leads to a rate of radiative decay faster than the non-radiative outcome. This mode of emission can be achieved with metal complexes, as reported by Baldo et al. in Nature 395, 151-154 (1998).

Particular preference is given to an emitter selected from the group of the fluorescent emitters.

Many examples of fluorescent emitters have already been published, for example styrylamine derivatives as disclosed in JP 2913116 B and in WO 2001/021729 A1, and indenofluorene derivatives as disclosed, for example in WO 2008/006449 and in WO 2007/140847.

The fluorescent emitters are preferably polyaromatic compounds, for example 9,10-di(2-naphthylanthracene) and other anthracene derivatives, derivatives of tetracene, xanthene, perylene, for example 2,5,8,11-tetra-t-butylperylene, phenylene, e.g. 4,4′-(bis(9-ethyl-3-carbazovinylene)-1,1′-biphenyl, fluorene, arylpyrenes (US 2006/0222886), arylenevinylenes (U.S. Pat. No. 5,121,029, U.S. Pat. No. 5,130,603), derivatives of rubrene, coumarin, rhodamine, quinacridone, for example N,N′-dimethylquinacridone (DMQA), dicyanomethylenepyran, for example 4-(dicyanoethylene)-6-(4-dimethylaminostyryl-2-methyl)-4H-pyran (DCM), thiopyrans, polymethine, pyrylium and thiapyrylium salts, periflanthene, indenoperylene, bis(azinyl)imine-boron compounds (US 2007/0092753 A1), bis(azinyl)methane compounds and carbostyryl compounds.

Further preferred fluorescent emitters are described in C. H. Chen et al.: “Recent developments in organic electroluminescent materials” Macromol. Symp. 125, (1997), 1-48 and “Recent progress of molecular organic electroluminescent materials and devices” Mat. Sci. and Eng. R, 39 (2002), 143-222.

Further preferred fluorescent emitters are selected from the class of the monostyrylamines, the distyrylamines, the tristyrylamines, the tetrastyrylamines, the styrylphosphines, the styryl ethers and the arylamines.

A monostyrylamine is understood to mean a compound containing one substituted or unsubstituted styryl group and at least one preferably aromatic amine. A distyrylamine is understood to mean a compound containing two substituted or unsubstituted styryl groups and at least one preferably aromatic amine. A tristyrylamine is understood to mean a compound containing three substituted or unsubstituted styryl groups and at least one preferably aromatic amine. A tetrastyrylamine is understood to mean a compound containing four substituted or unsubstituted styryl groups and at least one preferably aromatic amine. The styryl groups are more preferably stilbenes which may also have further substitution. The corresponding phosphines and ethers are defined analogously to the amines. For the purposes of the present application, an arylamine or an aromatic amine is understood to mean a compound containing three substituted or unsubstituted aromatic or heteroaromatic ring systems bonded directly to the nitrogen. At least one of these aromatic or heteroaromatic ring systems is preferably a fused ring system, more preferably having at least 14 aromatic ring atoms. Preferred examples of these are aromatic anthracenamines, aromatic anthracenediamines, aromatic pyrenamines, aromatic pyrenediamines, aromatic chrysenamines and aromatic chrysenediamines. An aromatic anthracenamine is understood to mean a compound in which one diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyrenamines, pyrenediamines, chrysenamines and chrysenediamines are defined analogously thereto, where the diarylamino groups in the pyrene are bonded preferably in the 1 position or in the 1,6 positions.

Further preferred fluorescent emitters are selected from indenofluorenamines and indenofluorenediamines, for example according to WO 2006/122630, benzoindenofluorenamines and benzoindenofluorenediamines, for example according to WO 2008/006449, and dibenzoindenofluorenamines and dibenzoindenofluorenediamines, for example according to WO 2007/140847.

Examples of emitters from the class of the styrylamines are substituted or unsubstituted tristilbenamines or the dopants described in WO 2006/000388, in WO 2006/058737, in WO 2006/000389, in WO 2007/065549 and in WO 2007/115610. Distyrylbenzene and distyrylbiphenyl derivatives are described in U.S. Pat. No. 5,121,029. Further styrylamines can be found in US 2007/0122656 A1.

Particularly preferred styrylamine emitters and triarylamine emitters are the compounds of the following formulae (35) to (40), as disclosed, for example, in U.S. Pat. No. 7,250,532 B2, in DE 102005058557 A1, in CN 1583691 A, in JP 08053397 A, in U.S. Pat. No. 6,251,531 B1 and in US 2006/210830 A.

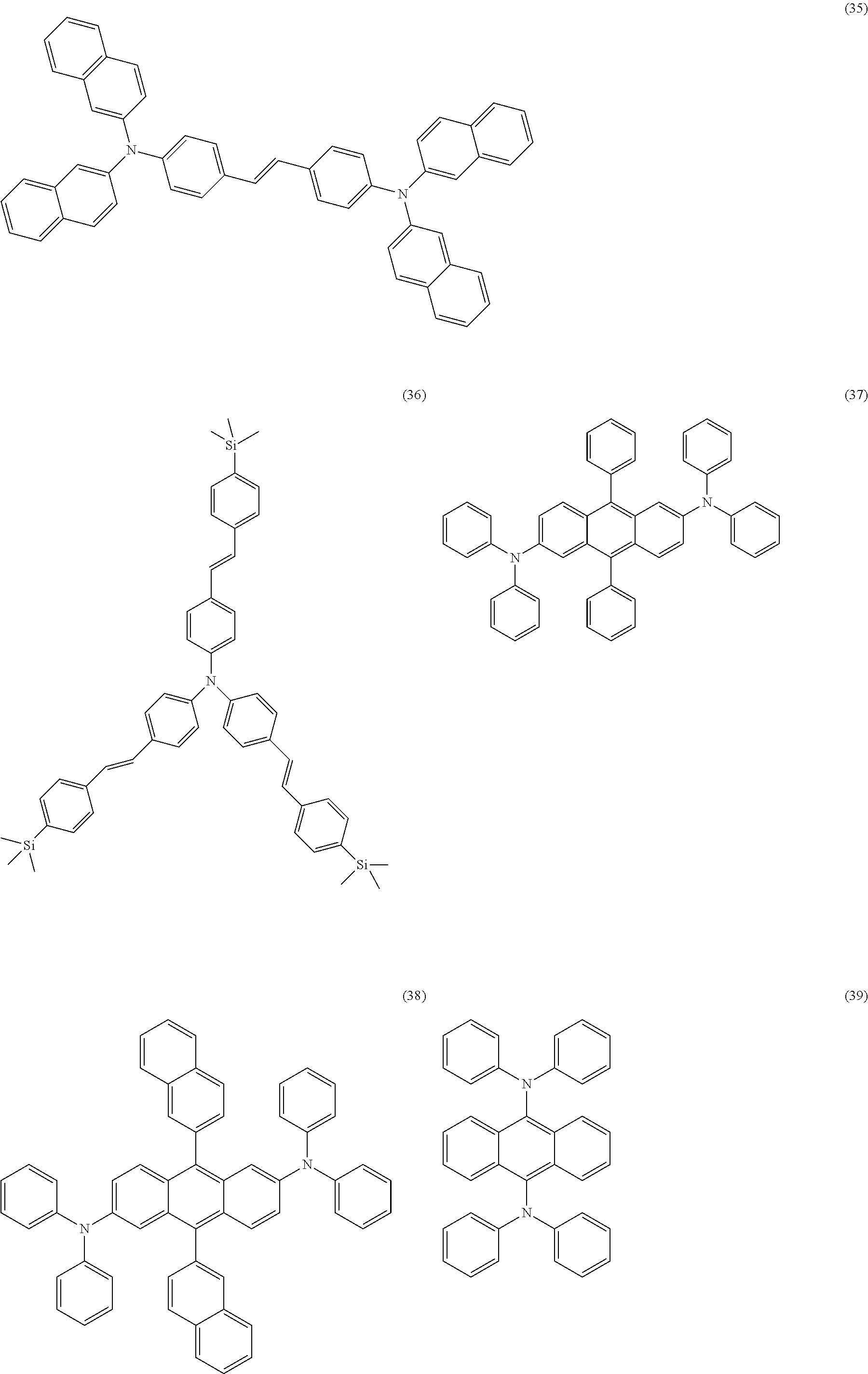

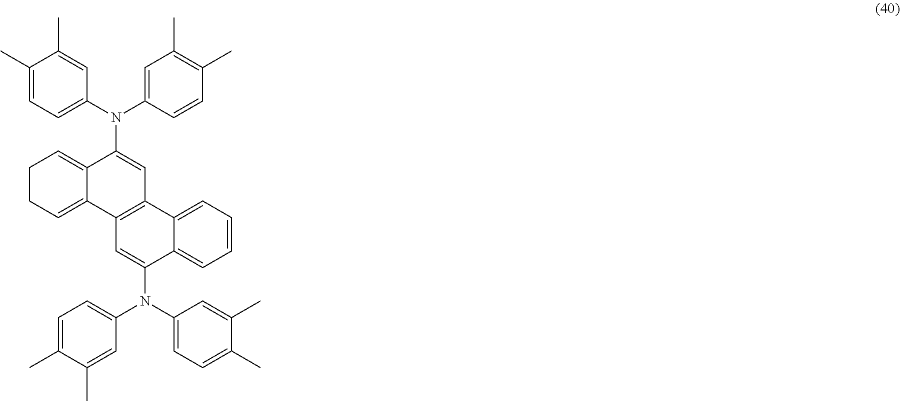

Further preferred fluorescent emitters are selected from the group of the triarylamines, as disclosed, for example, in EP 1957606 A1 and in US 2008/0113101 A1.

Further preferred fluorescent emitters are selected from the derivatives of naphthalene, anthracene, tetracene, fluorene, periflanthene, indenoperylene, phenanthrene, perylene (US 2007/0252517 A1), pyrene, chrysene, decacyclene, coronene, tetraphenylcyclopentadiene, pentaphenylcyclopentadiene, fluorene, spirofluorene, rubrene, coumarin (U.S. Pat. No. 4,769,292, U.S. Pat. No. 6,020,078, US 2007/0252517 A1), pyran, oxazone, benzoxazole, benzothiazole, benzimidazole, pyrazine, cinnamic esters, diketopyrrolopyrrole, acridone and quinacridone (US 2007/0252517 A1).

Among the anthracene compounds, 9,10-substituted anthracenes, for example 9,10-diphenylanthracene and 9,10-bis(phenylethynyl)anthracene, are particularly preferred. 1,4-Bis(9′-ethynylanthracenyl)benzene is likewise a preferred dopant.

More preferably, one emitter in the emitter layer is selected from the group of the blue-fluorescing emitters.

More preferably, one emitter in the emitter layer is selected from the group of the green-fluorescing emitters.

More preferably, one emitter in the emitter layer is selected from the group of the yellow-fluorescing emitters.

More preferably, one emitter in the emitter layer is selected from the group of the red-fluorescing emitters, especially from the group of the perylene derivatives of the formula (41), as disclosed, for example, in US 2007/0104977 A1.

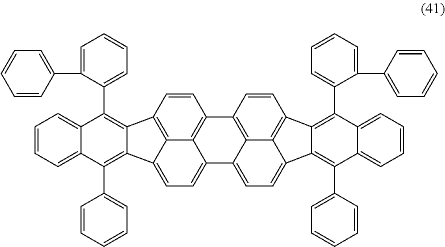 [SMILES: c1ccc(-c2ccccc2-c2c3c(c(-c4ccccc4)c4ccccc24)-c2ccc4c5ccc6c7c(ccc(c8ccc-3c2c48)c75)-c2c-6c(-c3ccccc3)c3ccccc3c2-c2ccccc2-c2ccccc2)cc1]

Particular preference is likewise given to an emitter in the emitter layer selected from the group of the phosphorescent emitters.

Examples of phosphorescent emitters are disclosed in WO 00/70655, in WO 01/41512, in WO 02/02714, in WO 02/15645, in EP 1191613, in EP 1191612, in EP 1191614 and in WO 2005/033244. In general, all phosphorescent complexes as used according to the prior art and as known to those skilled in the art in the field of organic electroluminescence are suitable, and the person skilled in the art will be able to use further phosphorescent complexes without exercising inventive skill.

The phosphorescent emitter may be a metal complex, preferably of the formula M(L)_{z} in which M is a metal atom, L independently at each instance is an organic ligand bonded or coordinated to M via one, two or more positions, and z is an integer ≧1, preferably 1, 2, 3, 4, 5 or 6, and in which these groups are optionally joined to a polymer via one or more, preferably one, two or three, positions, preferably via the ligands L.

M is a metal atom selected from transition metals, preferably from transition metals of group VIII, the lanthanides and actinides, more preferably from Rh, Os, Ir, Pt, Pd, Au, Sm, Eu, Gd, Tb, Dy, Re, Cu, Zn, W, Mo, Pd, Ag and Ru and especially from Os, Ir, Ru, Rh, Re, Pd and Pt. M may also be Zn.

Preferred ligands are 2-phenylpyridine derivatives, 7,8-benzoquinoline derivatives, 2-(2-thienyl)pyridine derivatives, 2-(1-naphthyl)pyridine derivatives or 2-phenylquinoline derivatives. These compounds may each be substituted, for example by fluorine or trifluoromethyl substituents for blue. Secondary ligands are preferably acetylacetonate or picric acid.

Suitable complexes with particular preference are those of Pt or Pd with tetradentate ligands of the formula (42), as disclosed in US 2007/0087219 A1, in which R¹ to R¹⁴ and Z¹ to Z⁵ are as defined in the reference, Pt-porphyrin complexes having an enlarged ring system (US 2009/0061681 A1) and Ir complexes, for example 2,3,7,8,12,13,17,18-octaethyl-21H,23H-porphyrin-Pt(II), tetraphenyl-Pt(II)-tetrabenzoporphyrin (US 2009/0061681 A1), cis-bis(2-phenylpyridinato-N,C2′)Pt(II), cis-bis(2-(2′-thienyl)pyridinato-N,C3′)Pt(II), cis-bis(2-(2′-thienyl)quinolinato-N,C5′)Pt(II), (2-(4,6-difluorophenyl)pyridinato-N,C2′)Pt(II) acetylacetonate or tris(2-phenylpyridinato-N,C2′)Ir(III) (Ir(ppy)₃, green), bis(2-phenylpyridinato-N,C2)Ir(III) acetylacetonate (Ir(ppy)₂ acetylacetonate, green, US 2001/0053462 A1, Baldo, Thompson et al. Nature 403, (2000), 750-753), bis(1-phenylisoquinolinato-N,C2′)(2-phenylpyridinato-N,C2′)iridium(III), bis(2-phenylpyridinato-N,C2′)(1-phenylisoquinolinato-N,C2′)iridium(III), bis(2-(2′-benzothienyl)pyridinato-N,C3′)iridium(III) acetylacetonate, bis(2-(4′,6′-difluorophenyl)pyridinato-N,C2′)iridium(III) picolinate (Firpic, blue), bis(2-(4′,6′-difluorophenyl)pyridinato-N,C2′)Ir(III) tetrakis(1-pyrazolyl)borate, tris(2-(biphenyl-3-yl)-4-tert-butylpyridine)iridium(III), (ppz)₂Ir(5phdpym) (US 2009/0061681 A1), (45ooppz)₂Ir(5phdpym) (US 2009/0061681 A1), derivatives of 2-phenylpyridine-Ir complexes, for example iridium(III) bis(2-phenylquinolyl-N,C2′) acetylacetonate (PQIr), tris(2-phenylisoquinolinato-N,C)Ir(III) (red), bis(2-(2′-benzo[4,5-a]thienyl)pyridinato-N,C3)Ir acetylacetonate ([Btp2Ir(acac)], red, Adachi et al. Appl. Phys. Lett. 78 (2001), 1622-1624).

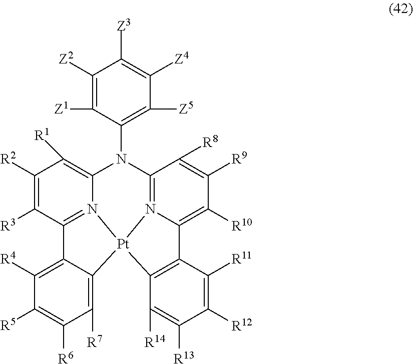

Likewise suitable are complexes of trivalent lanthanides, for example Tb³⁺ and Eu³⁺ (J. Kido et al. Appl. Phys. Lett. 65 (1994), 2124, Kido et al. Chem. Lett. 657, 1990, US 2007/0252517 A1) or phosphorescent complexes of Pt(II), Ir(I), Rh(I) with maleonitrile dithiolate (Johnson et al., JACS 105, 1983, 1795), Re(I)-tricarbonyldiimine complexes (inter alia Wrighton, JACS 96, 1974, 998), Os(II) complexes with cyano ligands and bipyridyl or phenanthroline ligands (Ma et al., Synth. Metals 94, 1998, 245) or Alq₃.

Further phosphorescent emitters having tridentate ligands are described in U.S. Pat. No. 6,824,895 and in U.S. Pat. No. 7,029,766. Red-emitting phosphorescent complexes are disclosed in U.S. Pat. No. 6,835,469 and in U.S. Pat. No. 6,830,828.

A particularly preferred phosphorescent emitter is a compound of the formula (43) and further compounds as disclosed, for example, in US 2001/0053462 A1.

A further particularly preferred phosphorescent emitter is a compound of the formula (44) and further compounds as disclosed, for example, in WO 2007/095118 A1.

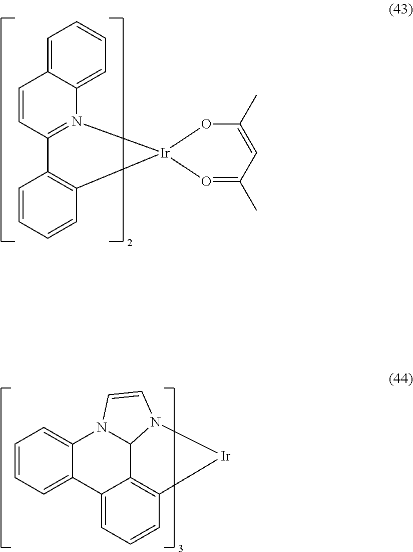

Further derivatives are described in U.S. Pat. No. 7,378,162 B2, in U.S. Pat. No. 6,835,469 B2 and in JP 2003/253145 A.

More preferably, the emitter in the emitter layer is selected from groups comprising organometallic complexes.

In addition to the metal complexes mentioned elsewhere in this document, a suitable metal complex according to the present invention is selected from transition metals, rare earth elements, lanthanides and actinides. The metal is preferably selected from Ir, Ru, Os, Eu, Au, Pt, Cu, Zn, Mo, W, Rh, Pd and Ag.

In a preferred embodiment, the emitter layer comprises a non-conjugated polymer containing at least one repeat unit containing an emitter group as described above. Examples of conjugated polymers containing metal complexes and the synthesis methods therefor are disclosed in EP 1138746 B1 and in DE 102004032527 A1. Examples of conjugated polymers containing singlet emitters and the synthesis methods therefor are disclosed in DE 102005060473 A1 and WO 2010/022847.

In a further preferred embodiment, the emitter layer comprises a non-conjugated polymer containing at least one emitter unit as described above and at least one pendant charge transport unit. Examples of non-conjugated polymers containing pendant metal complexes and the synthesis methods therefor are disclosed in U.S. Pat. No. 7,250,226 B2, in JP 2007/211243 A2, in JP 2007/197574 A2, in U.S. Pat. No. 7,250,226 B2 and in JP 2007/059939 A. Examples of non-conjugated polymers containing pendant singlet emitters and the synthesis methods therefor are disclosed in JP 2005/108556, in JP 2005/285661 and in JP 2003/338375.

In a further embodiment, the emitter layer comprises a non-conjugated polymer containing at least one emitter unit as described above and at least one repeat unit which forms the polymer backbone in the main chain, in which case the repeat unit which forms the polymer backbone is preferably selected from the units as described above for the interlayer polymer, non-conjugated backbone. Examples of non-conjugated polymers containing metal complexes in the main chain and the synthesis methods therefor are disclosed in WO 2010/149261 and in WO 2010/136110.

In yet a further preferred embodiment, a material used for the emitter layers comprises a charge-transporting polymer matrix as well as the emitter(s).

For fluorescent emitters or singlet emitters, this polymer matrix may be selected from a conjugated polymer preferably containing a non-conjugated polymer backbone as described above for the interlayer polymer and more preferably a conjugated polymer backbone as described above for the interlayer polymer. For phosphorescent emitters or triplet emitters, this polymer matrix is preferably selected from non-conjugated polymers which are non-conjugated side chain polymers or non-conjugated main chain polymers, for example polyvinylcarbazole (“PVK”), polysilane, copolymers containing phosphine oxide units or matrix polymers as described in WO 2010/149261 and in WO 2010/136110.

In yet a further preferred embodiment, the emitter layer comprises at least one low molecular weight emitter containing an emitter group as described above and at least one low molecular weight matrix material. Suitable low molecular weight matrix materials are materials from various substance classes.

Preferred matrix materials for fluorescent or singlet emitters are selected from the classes of the oligoarylenes (e.g. 2,2′,7,7′-tetraphenylspirobifluorene according to EP 676461 or dinaphthylanthracene), especially of the fused oligoarylenes containing aromatic groups, for example phenanthrene, tetracene, coronene, chrysene, fluorene, spirobifluorene, perylene, phthaloperylene, naphthaloperylene, decacyclene, rubrene, the oligoarylenevinylenes (e.g. 4,4′-bis(2,2-diphenylethenyl)-1,1′-biphenyl (DPVBi) or 4,4-bis-2,2-diphenylvinyl-1,1-spirobiphenyl (spiro-DPVBi according to EP 676461), the polypodal metal complexes (for example according to WO 04/081017), especially metal complexes of 8-hydroxyquinoline, e.g. aluminum(III) tris(8-hydroxyquinoline) (aluminum quinolate, Alq₃) or bis(2-methyl-8-quinolinolato)-4-(phenylphenolinolato)aluminum, including with imidazole chelate (US 2007/0092753 A1) and quinoline-metal complexes, aminoquinoline metal complexes, benzoquinoline metal complexes, the hole-conducting compounds (for example according to WO 04/058911), the electron-conducting compounds, especially ketones, phosphine oxides, sulfoxides, etc. (for example according to WO 05/084081 and WO 05/084082), the atropisomers (for example according to WO 06/048268), the boronic acid derivatives (for example according to WO 06/117052) or the benzanthracenes (for example according to DE 102007024850). Particularly preferred host materials are selected from the classes of the oligoarylenes comprising naphthalene, anthracene, benzanthracene and/or pyrene or atropisomers of these compounds, the ketones, the phosphine oxides and the sulfoxides. Very particularly preferred host materials are selected from the classes of the oligoarylenes comprising anthracene, benzanthracene and/or pyrene, or atropisomers of these compounds. For the purposes of the present application, an oligoarylene is understood to mean a compound in which at least three aryl or arylene groups are bonded to one another.

Particularly preferred low molecular weight matrix materials for singlet emitters are selected from benzanthracene, anthracene, triarylamine, indenofluorene, fluorene, spirobifluorene, phenanthrene, dihydrophenanthrene and the isomers and derivatives thereof.

Preferred low molecular weight matrix materials for phosphorescent or triplet emitters are N,N-biscarbazolylbiphenyl (CBP), carbazole derivatives (for example according to WO 05/039246, US 2005/0069729, JP 2004/288381, EP 1205527 or DE 102007002714), azacarbazoles (for example according to EP 1617710, EP 1617711, EP 1731584 or JP 2005/347160), ketones (for example according to WO 04/093207), phosphine oxides, sulfoxides and sulfones (for example according to WO 05/003253), oligophenylenes, aromatic amines (for example according to US 2005/0069729), bipolar matrix materials (for example according to WO 07/137725), 1,3,5-triazine derivatives (for example according to U.S. Pat. No. 6,229,012 B1, U.S. Pat. No. 6,225,467 B1, DE 10312675 A1, WO 98/04007 A1 and U.S. Pat. No. 6,352,791 B1), silanes (for example according to WO 05/111172), 9,9-diaryifluorene derivatives (for example according to DE 102008017591), azaboroles or boronic esters (for example according to WO 06/117052), triazole derivatives, oxazoles and oxazole derivatives, imidazole derivatives, polyarylalkane derivatives, pyrazoline derivatives, pyrazolone derivatives, distyrylpyrazine derivatives, thiopyran dioxide derivatives, phenylenediamine derivatives, tertiary aromatic amines, styrylamines, amino-substituted chalcone derivatives, indoles, styrylanthracene derivatives, aryl-substituted anthracene derivatives, for example 2,3,5,6-tetramethylphenyl-1,4-(bisphthalimide) (TMPP, US 2007/0252517 A1), anthraquinodimethane derivatives, anthrone derivatives, fluorenone derivatives, fluorenylidenemethane derivatives, hydrazone derivatives, stilbene derivatives, silazane derivatives, aromatic dimethylidene compounds, porphyrin compounds, carbodiimide derivatives, diphenylquinone derivatives, tetracarbocyclic compounds, for example naphthaleneperylene, phthalocyanine derivatives, metal complexes of the 8-hydroxyquinoline derivatives, for example AIq3, the 8-hydroxyquinoline complexes may also contain triarylaminophenol ligands (US 2007/0134514 A1), various metal complex-polysilane compounds with metal phthalocyanine, benzoxazole or benzothiazole as ligand, or electron-conducting polymers, for example poly(N-vinylcarbazole) (PVK), aniline copolymers, thiophene oligomers, polythiophenes, polythiophene derivatives, polyphenylene derivatives, polyphenylenevinylene derivatives and polyfluorene derivatives.

Particularly preferred low molecular weight matrix materials for triplet emitters are selected from carbazole, ketone, triazine, imidazole, fluorene, spirobifluorene, phenanthrene, dihydrophenanthrene and the isomers and derivatives thereof.

A further preferred material used for emitter layers comprises, as well as the emitter(s), an uncharged polymer matrix, for example polystyrene, polymethylmethacrylate, polyvinyl butyral (“PVB”) or polycarbonate.

A further preferred material used for emitter layers contains, as well as the emitter(s) and at least one polymer, at least one hole-transporting small molecule and/or at least one electron-transporting small molecule. These are understood to mean non-polymeric organic compounds having hole- or electron-transporting properties.

A preferred material used for emitter layers comprises, as well as the emitter(s), a material having electron-transporting properties.

Preference is given to using a polymeric matrix material containing one or more different triplet emitters incorporated within the polymer skeleton, or mixtures of polymeric matrix materials, in which case the polymers contain one or more different triplet emitters incorporated within the polymer skeleton.

The emitters in the emitter layer are preferably chosen so as to result in a maximum breadth of emission. Preference is given to combining triplet emitters having the following emissions: green and red; blue and green; bright blue and bright red; blue, green and red. Among these, particular preference is given to using triplet emitters having deep green and deep red emission. Good adjustment of yellow hues in particular is possible using these. Via the variation of the concentrations of the individual emitter molecules, it is possible to create and adjust the hues in the desired manner.

Emitters used in the context of this application can be any molecules which emit from the singlet or triplet state within the visible spectrum. The “visible spectrum” in the context of this application is understood to mean a region having a wavelength in the range from 380 nm to 750 nm.

Particular preference is given to electroluminescent devices in which a first emitter has an emission maximum in the green spectral region and a second emitter an emission maximum in the red spectral region. Further preferred combinations of emitters are those having an emission maximum in the blue and green spectral region, in the bright blue and bright red spectral region, and in the blue, green and red spectral region.

In general, the emitters are present in the emitter layer in a dopant-matrix system. The concentration of emitter(s) is preferably in the range from 0.01 to 30 mol %, more preferably in the range from 1 to 25 mol % and especially in the range from 2 to 20 mol %.

More preferably, the emitter layer comprises charge-transporting substances.

In a further preferred embodiment, the electrooptical device of the invention comprises, in the emitter layer, triplet emitters and substances which promote the transfer of excitation energy to the triplet state. These are, for example, carbazoles, ketones, phosphine oxides, silanes, sulfoxides, compounds having heavy metal atoms, bromine compounds or phosphorescence sensitizers.

Particular preference is given to electrooptical devices in which the semiconductive organic material in the emitter layer is a semiconductive polymer, especially a semiconductive copolymer.

The latter preferably comprises semiconductive copolymers having repeat units which derive from fluorene, spirobifluorene, indenofluorene, phenanthrene, dihydrophenanthrene, phenylene, dibenzothiophene, dibenzofuran, phenylenevinylene and derivatives thereof, where these repeat units may optionally be substituted.

Further preferred semiconductive copolymers used in the emitter layer have repeat units which derive from triarylamines, preferably from those having repeat units of the above-defined formulae (19) to (21).

The electrooptical devices of the invention more preferably have a very simple structure. In the extreme case, the device may be one comprising, as well as a cathode layer and anode layer, only one or more emitter layers disposed in between and one or more interlayers.

A preferred embodiment of the electrooptical device of the invention comprises at least one additional electron injection layer disposed directly between the first emitter layer and the cathode.

Preferably, the electrooptical device of the invention is applied to a substrate, especially to a transparent substrate. Applied in turn thereto is preferably an electrode made from transparent or semitransparent material, preferably made from indium tin oxide.

More particularly, the electrooptical device further comprises a hole injection layer disposed between anode and interlayer composed of hole-conducting polymer, preferably a layer composed of poly(ethylenedioxythiophene).

The electrooptical devices of the invention preferably have thicknesses of the mutually delimited individual layers in the range from 1 to 150 nm, more preferably in the range from 3 to 100 nm and especially in the range from 5 to 80 nm.

Preferred electrooptical devices of the invention comprise polymeric materials having glass transition temperatures T_{g} of greater than 90° C., more preferably of greater than 100° C. and especially of greater than 120° C.

It is particularly preferable when all polymers used in the device of the invention have the high glass transition temperatures described.

Cathode materials used in the electrooptical devices of the invention may be materials known per se. Especially for OLEDs, materials having a low work function are used. Examples of these are metals, metal combinations or metal alloys having a low work function, for example Ca, Sr, Ba, Cs, Mg, Al, In and Mg/Ag.

The construction of the electrooptical devices of the invention can be achieved by various production methods.

Firstly, it is possible to apply at least some of the layers under reduced pressure; some of the layers, especially the emitter layer(s) and the interlayer(s), are applied from solution. It is also possible without exercising inventive skill to apply all the layers from solution.

In the case of application under reduced pressure, structuring is accomplished using shadowmasks, while a wide variety of different printing processes are employable from solution.

Printing methods in the context of the present application also include those which proceed from solids, such as thermal transfer or LITI.

In the case of the solvent-based methods, solvents which dissolve the substances used are used. The nature of the substance is not crucial to the invention.

The electrooptical devices of the invention can thus be produced by methods known per se, with application at least of the at least one emitter layer and an interlayer from solution, preferably by a printing method, more preferably by inkjet printing.

In a preferred embodiment, the electrooptical device of the invention is an organic light-emitting diode (OLED).

In a further preferred embodiment, the electrooptical device of the invention is an organic light-emitting electrochemical cell (OLEC) containing two electrodes and at least one emitter layer and an interlayer between the emitter layer and an electrode as described above, which is characterized in that the emitter layer contains at least one further ionic compound. The original work and the principle of OLECs can be traced back to the article by Qibing Pei et al., Science, 1995, 269, 1086-1088.

The electrooptical device of the invention can especially be used in various applications; particularly preferred applications include: information displays, backlighting and general lighting. A further particular field of use of the electrooptical device of the invention is therapeutic and cosmetic treatment applications, as disclosed, for example, in EP 1444008 and GB 24082092.

These uses likewise form part of the subject matter of the present application.

The examples which follow elucidate the invention without restricting it.

### EXAMPLES 1 AND 2

### Monomer Examples

In order to be able to prepare the polymers of the invention, it was first necessary to convert electron-transporting compounds to monomers.

### EXAMPLE 1

A preferred monomer unit corresponds to formula (1) which was prepared as follows:

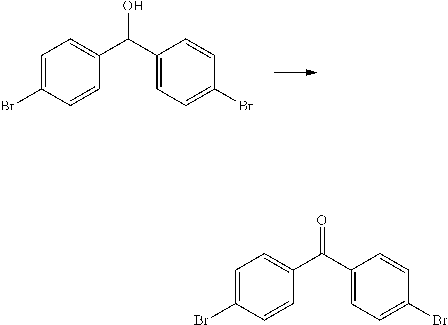

A four-neck flask is initially charged with one equivalent of the alcohol in dichloromethane and stirred under protective gas for 30 minutes. Manganese(IV) oxide (precipitated, active, 99%) is added to the synthesis in small portions. In the course of this, the temperature rises from 18° C. to 25° C. after the first half of 5 equivalents has been added. The reaction mixture is cooled with a water bath, while the remaining 2.5 equivalents are added gradually. Thereafter, the mixture is stirred overnight. The product is filtered with suction through silica gel, washed with dichloromethane, concentrated to dryness, extracted by stirring with ethanol at room temperature, filtered off with suction and dried in a vacuum drying cabinet at 40° C. for 24 hours. The yield at this point is 70%. Purification is effected over several extractive stirring and recrystallization steps (from ethanol, methanol/acetone, toluene and toluene/heptane) until a purity of 99.95% is attained.

### EXAMPLE 2

A further unit suitable as an electron conductor in an interlayer because of its LUMO of −2.7 eV is as follows:

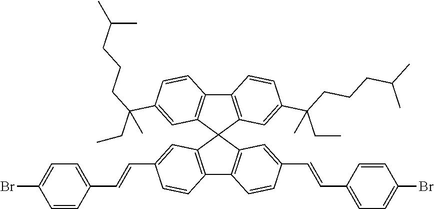 [SMILES: CCC(C)(CCCC(C)C)c1ccc2c(c1)C1(c3cc(/C=C/c4ccc(Br)cc4)ccc3-c3ccc(/C=C/c4ccc(Br)cc4)cc31)c1cc(C(C)(CC)CCCC(C)C)ccc1-2]

The preparation of this monomer is described in WO 03/020790.

### EXAMPLES 3 TO 7

### Polymer Examples

The polymers P1 to P4 of the invention and the comparative polymer C1 are synthesized using the following monomers (percentages=mol %) by SUZUKI coupling in accordance with WO 03/048225 A2. The synthesis of light-emitting polymers having the monomers mentioned is disclosed in WO 05/040302 and in WO 03/020790.

### EXAMPLE 3

### Polymer P1

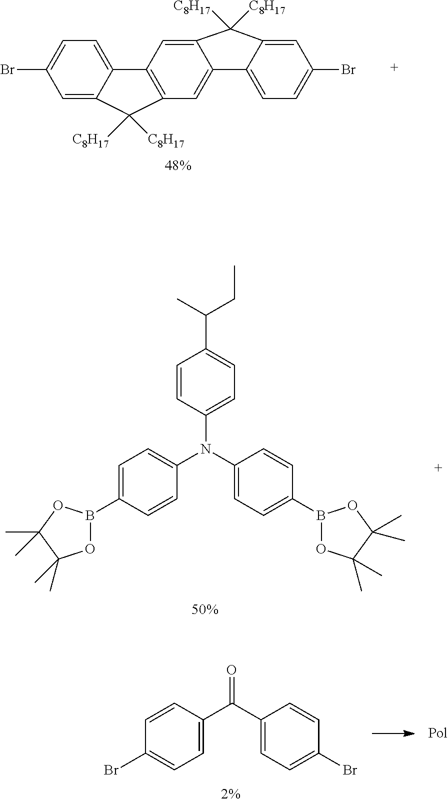

### EXAMPLE 4

### Polymer P2

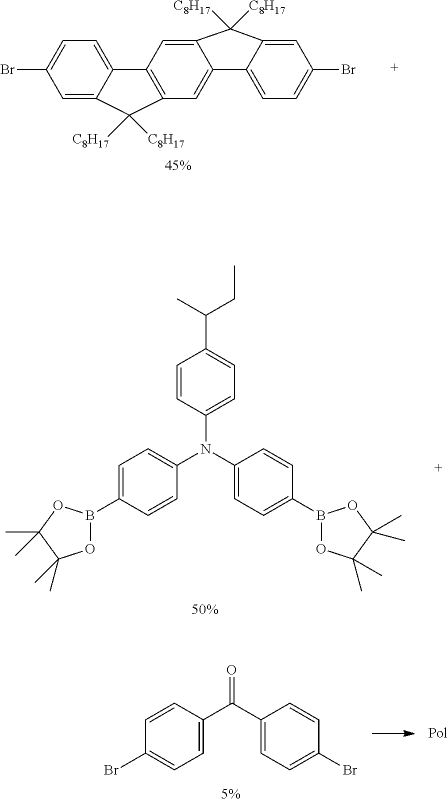

### EXAMPLE 5

### Polymer P3

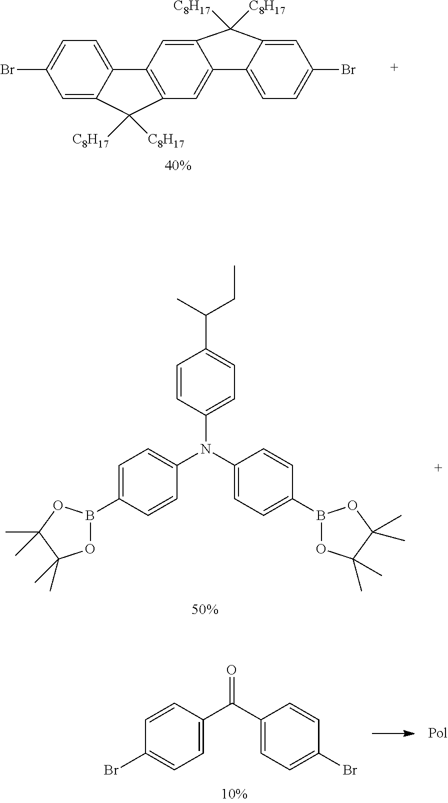

### EXAMPLE 6

### Polymer P4

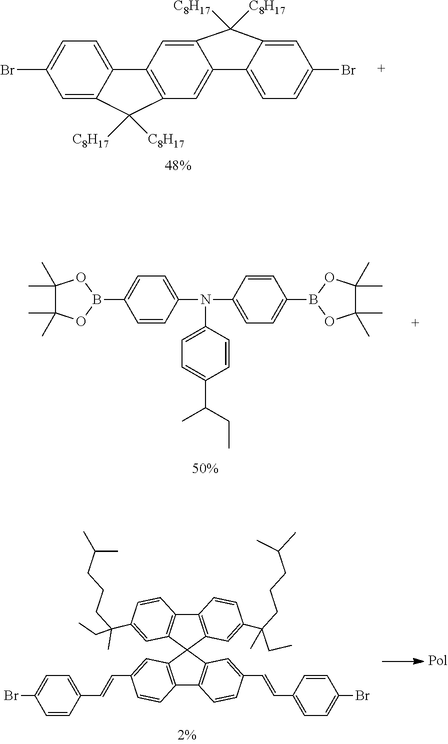

### EXAMPLE 7

### Comparative Polymer C1

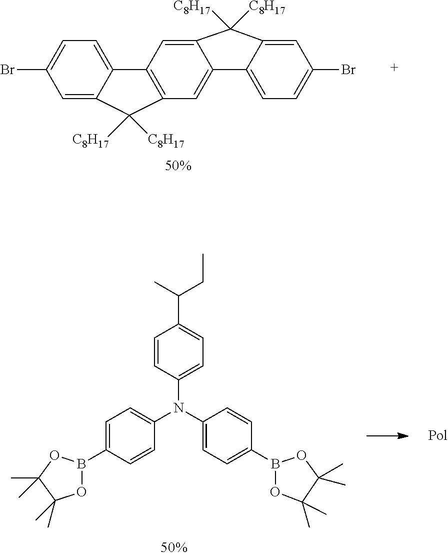

### EXAMPLES 8 TO 18

### Device Examples

### Production of PLEDs

There have already been many descriptions of the production of a polymeric organic light-emitting diode (PLED) in the literature (for example in WO 2004/037887 A2). In order to illustrate the present invention by way of example, PLEDs are produced with polymers P1 to P4 and comparative polymer C1 by spin-coating. A typical device has the structure described hereinafter.

For this purpose, specially manufactured substrates from Technoprint are used in a layout specially designed for this purpose. The ITO structure (indium tin oxide, a transparent conductive anode) is applied to soda-lime glass by sputtering in such a pattern that the cathode applied by vapor deposition at the end of the production process results in 4 pixels of 2×2 mm.

The substrates are cleaned in a cleanroom with DI water and a detergent (Deconex 15 PF) and then activated by a UV/ozone plasma treatment. Thereafter, likewise in the cleanroom, an 80 nm layer of PEDOT (PEDOT is a polythiophene derivative (Clevios P 4083 AI) from H. C. Starck, Goslar, which is supplied as an aqueous dispersion) is applied by spin-coating. The required spin rate depends on the degree of dilution and the specific spin-coater geometry (typical value for 80 nm: 4500 rpm). In order to remove residual water from the layer, the substrates are baked on a hotplate at 180° C. for 10 minutes. Thereafter, 20 nm of an interlayer are first spun on under an inert gas atmosphere (nitrogen or argon). In the present case, this comprises polymers P1 to P4 or C1, which are processed at a concentration of 5 g/l from toluene. All interlayers in these device examples are baked at 180° C. under inert gas for 1 hour. Subsequently, 65 nm of the polymer layers are applied from toluene solutions (typical concentrations 8 to 12 g/l). This polymer layer too is baked under inert gas after spin-coating, specifically at 180° C. for 10 minutes. Thereafter, the Ba/Al cathode (3 nm/100 nm) is applied by vapor deposition in the pattern specified through a vapor deposition mask (high-purity metals from Aldrich, particularly barium 99.99% (cat. no. 474711); vapor deposition systems from Lesker or the like, typical vacuum level 5×10⁻⁶ mbar). In order to protect the cathode in particular from air and air humidity, the device is finally encapsulated.

The device is encapsulated by bonding a commercially available glass cover over the pixelated area. Subsequently, the device is characterized.

For this purpose, the devices are clamped into holders manufactured specially for the substrate size and contact-connected by means of spring contacts. A photodiode with an eye response filter can be placed directly onto the analysis holder, in order to rule out any influences by outside light.

Typically, the voltages are increased from 0 to max. 20 V in 0.2 V steps and lowered again. For each measurement point, the current through the device and the photocurrent obtained are measured by the photodiode. In this manner, the IVL data of the test devices are obtained. Important characteristic parameters are the maximum efficiency measured (“Max. eff” in cd/A) and the voltage required for 100 cd/m².

In order also to find the color and the exact electroluminescence spectrum of the test devices, the first measurement is followed by application of the voltage required for 100 cd/m² once again and replacement of the photodiode with a spectrum measurement head. The latter is connected by an optical fiber to a spectrometer (Ocean Optics). The spectrum measured can be used to derive the color coordinates (CIE: Commission International de l'éclairage, standard observer from 1931).

A factor of particular significance for the usability of the materials is the lifetime of the devices. This is measured in a test setup very similar to the first evaluation, in such a way that a starting luminance is set (e.g. 1000 cd/m²). The current required for this luminance is kept constant, while the voltage typically rises and the luminance decreases. The lifetime has been attained when the initial luminance has dropped to 50% of the starting value. If an extrapolation factor has been determined, the lifetime can also be measured in an accelerated manner by setting a higher starting luminance. In this case, the measurement apparatus keeps the current constant, and so it shows the electrical degradation of the components in a voltage rise.

### EXAMPLES 8 TO 10

In the manner specified above, components are produced and characterized with 20 nm of P1 and P3 and 20 nm of C1. The light-emitting polymer used is a blue-emitting polymer SPB-036 from Merck. The results are collated in Table 1.

TABLE 1

| | | Max. eff. | U @ 100 | CIE | Lifetime |
|---|---|---|---|---|---|
| Example | Polymer | [cd/A] | cd/m² [V] | [x/y] | [h @ cd/m²] |
| 8 | P1 | 3.9 | 4.5 | 0.17/0.24 | 145 @ 800 |
| 9 | P3 | 3.8 | 4.5 | 0.17/0.24 | 100 @ 800 |
| 10 | C1 | 3.9 | 4.6 | 0.16/0.23 | 75 @ 800 |

### EXAMPLES 11 TO 13

A further comparison between blue devices is conducted with the polymer SPB-078 from Merck. The interlayers used here are polymers P2 and P4 and comparative polymer C1. The results are collated in Table 2. What is particularly noticeable here is the desirable better electrical stability of the devices resulting from use of the polymers of the invention, which is manifested in the distinctly smaller rise in voltage during the lifetime measurement.

TABLE 2

| | | Max. eff | U @ 100 | CIE | Lifetime | ΔV |
|---|---|---|---|---|---|---|
| Example | Polymer | [cd/A] | cd/m² [V] | [x/y] | [h @ cd/m²] | [mV/h] |
| 11 | P2 | 5.5 | 5.4 | 0.15/0.18 | 436 @ 1000 | 3.3 |
| 12 | P4 | 5.9 | 5.8 | 0.15/0.19 | 400 @ 1000 | 3.0 |
| 13 | C1 | 5.4 | 5.5 | 0.15/0.17 | 340 @ 1000 | 4.7 |

### EXAMPLES 14 AND 15

With white polymers too, it is possible to achieve an improvement in device lifetime, a reduction in operating voltage and a reduced rise in voltage. The interlayer polymers P1 and C1 are used here in conjunction with the white polymer SPW-110 from Merck.

TABLE 3

| | | Max. eff. | | CIE | Lifetime* | ΔV* |
|---|---|---|---|---|---|---|
| Example | Polymer | [cd/A] | U @ 100 cd/m² [V] | [x/y] | [h @ cd/m²] | [mV/h] |
| 14 | P1 | 6 9 | 6.9 | 0.38/0.39 | 1650 @ 1000 | 1.3 |
| 15 | C1 | 7.2 | 7.0 | 0.37/0.40 | 1400 @ 1000 | 2.8 |

*The lifetime measurement is conducted in an accelerated manner; the rise in voltage relates to a starting luminance of 2000 cd/m².

### EXAMPLES 16 TO 18

A further white polymer from Merck, SPW-138, is likewise used to produce devices in the manner described.

TABLE 4

| | | Max. | | | | |
|---|---|---|---|---|---|---|
| Ex- | Poly- | eff. | U @ 100 | CIE | Lifetime* | ΔV* |
| ample | mer | [cd/A] | cd/m² [V] | [x/y] | [h @ cd/m²] | [mV/h] |
| 16 | P1 | 13.4 | 3.2 | 0.36/0.44 | 3900 @ 1000 | 0.6 |
| 17 | P4 | 13.6 | 3.2 | 0.37/0.44 | 4100 @ 1000 | 0.75 |
| 18 | C1 | 12.9 | 3.2 | 0.38/0.43 | 2950 @ 1000 | 1.1 |

*The lifetime measurement is conducted in an accelerated manner; the rise in voltage relates to a starting luminance of 3000 cd/m².

As can be seen from the results, polymers P1 to P4 constitute a distinct improvement in important parameters of the device. Higher efficiencies, lower voltages in many cases, improved lifetimes and, even in the case of components having an extremely small rise in voltage, a further reduction once again are measured. The latter in particular means that the novel polymers of the invention are much better suited to use in displays and lighting applications than polymers according to the prior art, since they have better electrical stability.

1-17. (canceled)

18. An electro-optical device comprising:
a) an anode;
b) a cathode;
c) at least one emitter layer disposed between the anode and the cathode, comprising at least one semiconductive organic material; and
d) at least one interlayer which is disposed between the at least one emitter layer and the anode and comprises a polymer comprises hole-conducting structural units;
wherein the polymer comprising hole-conducting structural units additionally comprises structural units having electron-conducting properties.

19. The electro-optical device of claim 18, wherein the structural units having electron-conducting properties have a LUMO lower than the LUMO of the semiconductive organic material in the emitter layer.

20. The electro-optical device of claim 19, wherein the LUMO of the structural units having electron-conducting properties is less than −2.3 eV.

21. The electro-optical device of claim 18, wherein the structural units having electron-conducting properties are selected from the group consisting of the structural units of formulae (I) to (IV): 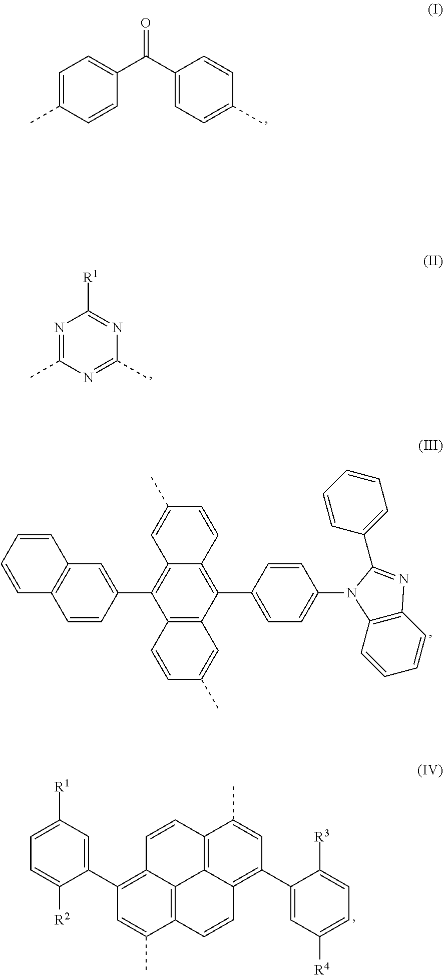
wherein
R¹ to R⁴
are each independently a hydrogen atom, a substituted or unsubstituted aromatic cyclic hydrocarbyl group having 6 to 50 carbon atoms in the ring, a substituted or unsubstituted aromatic heterocyclic group having 5 to 50 ring atoms, a substituted or unsubstituted alkyl group having 1 to 50 carbon atoms, a substituted or unsubstituted cycloalkyl group having 3 to 50 carbon atoms in the ring, a substituted or unsubstituted alkoxy group having 1 to 50 carbon atoms, a substituted or unsubstituted aralkyl group having 6 to 50 carbon atoms in the ring, a substituted or unsubstituted aryloxy group having 5 to 50 carbon atoms in the ring, a substituted or unsubstituted arylthio group having 5 to 50 carbon atoms in the ring, a substituted or unsubstituted alkoxycarbonyl group having 1 to 50 carbon atoms, a substituted or unsubstituted silyl group having 1 to 50 carbon atoms, a carboxyl group, a halogen atom, a cyano group, a nitro group, or a hydroxyl group, and
one or more of the pairs R¹ and R², R³ and R⁴, R⁵ and R⁶, and R⁷ and R⁸ optionally define a ring system.

22. The electro-optical device of claim 18, wherein the proportion of the structural units having electron-conducting properties in the hole-conducting polymer is in the range of from 0.01 to 30 mol %.

23. The electro-optical device of claim 18, wherein the hole-conducting polymer comprises triarylamines-derived structural units having hole-conducting properties.

24. The electro-optical device of claim 23, wherein the triarylamine is selected from the group consisting of structural units of formulae (19) to (21): 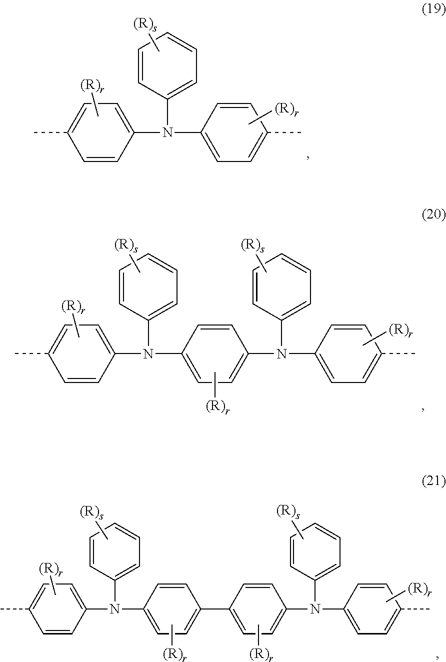
wherein
R may be the same or different in each instance and is selected from H, substituted or unsubstituted aromatic or heteroaromatic groups, alkyl groups, cycloalkyl groups, alkoxy groups, aralkyl groups, aryloxy groups, arylthio groups, alkoxycarbonyl groups, silyl groups, carboxyl groups, halogen atoms, cyano groups, nitro groups, and hydroxyl groups;
r is 0, 1, 2, 3, or 4; and
s is 0, 1, 2, 3, 4, or 5.

25. The electro-optical device of claim 18, wherein the hole-conducting polymer comprises repeat structural units derived from a fluorene, spirobifluorene, indenofluorene, phenanthrene, dihydrophenanthrene, dibenzothiophene, dibenzofuran, or derivatives thereof.

26. The electro-optical device of claim 18, wherein the semiconductive organic material of the emitter layer is a semiconductive polymer, preferably a semiconductive copolymer.

27. The electro-optical device of claim 18, wherein the semiconductive polymer is a semiconductive copolymer.

28. The electro-optical device of claim 27, wherein the semiconductive copolymer comprises repeat structural units derived from fluorene, spirobifluorene, indenofluorene, phenanthrene, dihydrophenanthrene, phenylene, dibenzothiophene, dibenzofuran, phenylenevinylene, derivatives thereof, each of which are optionally substituted.

29. The electro-optical device of claim 27, wherein the semiconductive copolymer comprises repeat units derived from triarylamines.

30. The electro-optical device of claim 29, wherein the triarylamine is selected from the group consisting of structural units of formulae (19) to (21): 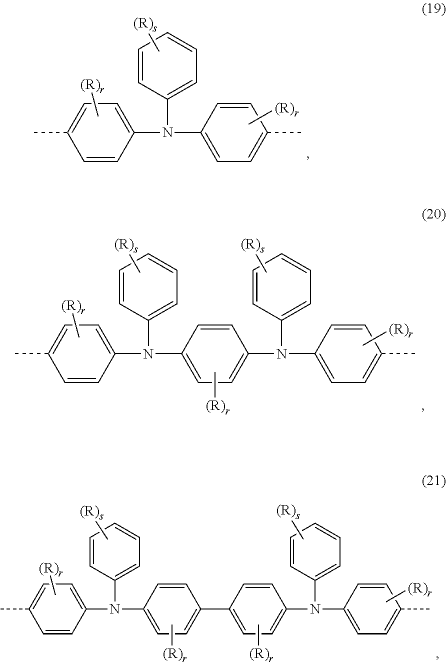
wherein
R may be the same or different in each instance and is selected from H, substituted or unsubstituted aromatic or heteroaromatic groups, alkyl groups, cycloalkyl groups, alkoxy groups, aralkyl groups, aryloxy groups, arylthio groups, alkoxycarbonyl groups, silyl groups, carboxyl groups, halogen atoms, cyano groups, nitro groups, and hydroxyl groups;
r is 0, 1, 2, 3, or 4; and
s is 0, 1, 2, 3, 4, or 5.

31. The electro-optical device of claim 18, further comprising a hole injection layer disposed between the anode and the interlayer composed of hole-conducting polymer.

32. The electro-optical device of claim 31, wherein the hole injection layer is a layer of poly(ethylenedioxythiophene).

33. The electro-optical device of claim 18, wherein the electro-optical device is disposed on a substrate.

34. The electro-optical device of claim 33, wherein the substrate is transparent.

35. The electro-optical device of claim 18, wherein the electro-optical device consists solely of an anode, a hole injection layer, an interlayer, one or more emitter layers, a hole blocker layer, an electron transport layer, and a cathode, and wherein the electro-optical device is optionally disposed on a transparent substrate.

36. The electro-optical device of claim 18, wherein the electro-optical device is an organic light-emitting diode or an organic light-emitting electrochemical cell.
